(19) United States
(12) Patent Application Publication
(10) Pub. No.: US 2025/0389790 A1
(43) Pub. Date: Dec. 25, 2025

(54) DETERMINING AND DIAGNOSING DEVICE

(71) Applicant: TOYOTA JIDOSHA KABUSHIKI KAISHA, Toyota-shi (JP)

(72) Inventors: Takanori SATAKE, Toyokawa-shi (JP); Takashi Nakane, Nagoya-shi (JP); Hao Shindo, Nagoya-shi (JP); Makoto Kuze, Chiryu-shi (JP); Taiki Ishida, Toyota-shi (JP); Shota Yamada, Okazaki-shi (JP); Fumiyoshi Kuribara, Toyota-shi (JP); Yutaka Kuboyama, Toyota-shi (JP); Yuki Wakida, Ichinomiya-shi (JP)

(73) Assignee: TOYOTA JIDOSHA KABUSHIKI KAISHA, Toyota-shi (JP)

(21) Appl. No.: 19/053,638

(22) Filed: Feb. 14, 2025

(30) Foreign Application Priority Data
Jun. 21, 2024 (JP) 2024-100472

(51) Int. Cl. G01R 31/52

(52) U.S. Cl. CPC G01R 31/52

(57) ABSTRACT

A determining and diagnosing device for determining whether a leakage current is generated based on a detection value from a detection unit that detects a current flowing between an power path and a predetermined location, and diagnosing a state of the detection unit, the device comprising: a connecting and disconnecting unit configured to connect and disconnect a resistor connected to the power path and a predetermined location; a determination diagnosis unit configured to determine whether a leakage current is generated based on the detection value and the first threshold value; and a determining and diagnosing unit configured to diagnose a state of the detection unit based on the detection value, the first threshold value, and a second threshold value that is different from the first threshold value, while executing a diagnosis control for controlling the connecting and disconnecting unit so that the power path and the predetermined location are connected.

### CROSS-REFERENCE TO RELATED APPLICATION

This application claims priority to Japanese Patent Application No. 2024-100472 filed on Jun. 21, 2024. The disclosure of the above-identified application, including the specification, drawings, and claims, is incorporated by reference herein in its entirety.

### BACKGROUND

### 1. Technical Field

The present disclosure relates to a determining and diagnosing device.

### 2. Description of Related Art

Conventionally, a device including a detection unit that detects a leakage current of a high-voltage direct current power supply that is installed in a vehicle, as a detection value of voltage, has been proposed as a device for determining whether a leakage current is occurring (e.g., see Japanese Unexamined Patent Application Publication No. 9-274062 (JP 9-274062 A)). In this device, a protective resistor, two detection resistors, and a protective resistor are connected in this order between a positive line and a negative line from the high-voltage direct current power supply, grounding is performed between the two detection resistors, and also a switch is connected in parallel to each protective resistor. Also, in this device, following standing by for a predetermined amount of time from controlling opening/closing of the switches, electric leakage is determined based on voltage across both ends of the detection resistors after discharging floating capacitance between the high-voltage direct current power supply and a body. Thus, occurrence of error in voltage across both ends of the detection resistors due to floating capacitance is suppressed, and whether leakage current is occurring is determined more appropriately.

### SUMMARY

However, the above literature does not disclose diagnosis of the state of the detection unit. When an abnormality occurs in the detection unit, whether a leakage current is occurring cannot be appropriately determined. Accordingly, diagnosing the state of the detection unit is recognized as being an important issue. As for a technique of diagnosing the state of the detection unit, a technique of diagnosing the detection unit during a standby period following controlling opening/closing of the switch is conceivable. However, with this technique, determination of whether a leakage current is occurring cannot be performed during diagnosis of the detection unit, i.e., during the standby period following controlling opening/closing of the switch.

A primary object of the determining and diagnosing device according to the present disclosure is to determine whether a leakage current is occurring while diagnosing the detection unit.

In order to achieve the above-described primary object, the determining and diagnosing device according to the present disclosure employs the following means.

The gist of a first determining and diagnosing device according to the present disclosure is
a determining and diagnosing device that determines whether a leakage current is occurring based on a detection value from a detection unit that detects a parameter reflecting a current flowing between a power path and a predetermined location, and also that diagnoses a state of the detection unit, the determining and diagnosing device including
a connecting and disconnecting unit for connecting and disconnecting a resistor that is connected to the power path and the predetermined location, and
a determining and diagnosing unit that determines whether the leakage current is occurring based on the detection value and a first threshold value, and also diagnoses the state of the detection unit based on the detection value, the first threshold value, and a second threshold value that is different from the first threshold value, while executing diagnosis control in which the connecting and disconnecting unit is controlled such that the power path and the predetermined location are connected via the resistor.

In the first determining and diagnosing device according to the present disclosure, determination is made regarding whether a leakage current is occurring based on the detection value and the first threshold value, and also the state of the detection unit is diagnosed based on the detection value, the first threshold value, and the second threshold value that is different from the first threshold value while executing the diagnosis control in which the connecting and disconnecting unit is controlled such that the power path and the predetermined location are connected. When diagnosis control is executed, the power path and the predetermined location are connected via the resistor, and a current due to discharge of the floating capacitance of the power path flows between the power path and the predetermined location. When the detection unit is normal, the detection value changes over a time constant due to the floating capacitance and the resistor, and stabilizes at a predetermined value between the first threshold value and the second threshold value. When an abnormality occurs in the detection unit, the detection value does not become a value between the first threshold value and the second threshold value. Accordingly, the detection unit can be diagnosed by diagnosing the state of the detection unit based on the detection value, the first threshold value, and the second threshold value that is different from the first threshold value, while executing diagnosis control. When a leakage current is occurring between the power path and the predetermined location during diagnosis control, a current due to discharge of the floating capacitance flows between the power path and the predetermined location without going through the resistor of the connecting and disconnecting unit, and the detection value changes over a smaller time constant than when the leakage current is not occurring, and exceeds the first threshold value. Accordingly, whether a leakage current is occurring is determined based on the detection value and the first threshold value, and also the state of the detection unit is diagnosed based on the detection value, the first threshold value, and the second threshold value that is different from the first threshold value, while executing diagnosis control in which the connecting and disconnecting unit is controlled such that the power path and the predetermined location are connected. Thus, whether a leakage current is occurring can be determined while diagnosing the detection unit. Now, examples of the “predetermined location” may include the ground, a housing of another device, or the like.

In this first determining and diagnosing device of the present disclosure, an arrangement may be made in which
the detection unit detects a current flowing between the power path and the predetermined location as a voltage, and
the determining and diagnosing unit
sets the second threshold value to be lower than the first threshold value,
determines that the leakage current is occurring when the detection value exceeds the first threshold value at a time rate of change that is no smaller than a predetermined rate, and diagnoses that an abnormality is occurring in the detection unit when the detection value exceeds the first threshold value during execution of the diagnosis control, and when the detection value is smaller than the second threshold value within a predetermined period during execution of the diagnosis control.

Accordingly, occurrence of the leakage current can be determined and diagnosis of an abnormality occurring in the detection unit can be performed, more appropriately.

Also, in the first determining and diagnosing device according to the present disclosure,
at least one of the first threshold value and the second threshold value may change over time in accordance with an amount of elapsed time since starting of the diagnosis control.
   This enables occurrence of an abnormality in the detection unit to be diagnosed more appropriately.

Further, in the first determining and diagnosing device according to the present disclosure,
the determining and diagnosing unit may
reduce the first threshold value before and after a first period that is between a first timing and a second timing after starting the diagnosis control, in comparison with during the first period, and
reduce the second threshold value before and after a second period that is between a third timing and a fourth timing after starting the predetermined period, in comparison with during the second period.
   This enables occurrence of an abnormality in the detection unit to be diagnosed more appropriately.

The gist of a second determining and diagnosing device according to the present disclosure is
a determining and diagnosing device that determines whether a leakage current is occurring based on a detection value from a detection unit that detects a current flowing between a power path and a predetermined location, and also that diagnoses a state of the detection unit,
the determining and diagnosing device including
a blocking unit that is configured to block and unblock a current flowing between the power path and the predetermined location, via a resistor; and
a determining and diagnosing unit that determines whether the leakage current is occurring based on the detection value and a first threshold value, and also diagnoses the state of the detection unit based on the detection value, and a second threshold value that changes over time, while executing diagnosis control in which the blocking unit is controlled such that the current between the power path and the predetermined location is unblocked.

In the second determining and diagnosing device according to the present disclosure, determination is made regarding whether a leakage current is occurring based on the detection value and the first threshold value, and also the state of the detection unit is diagnosed based on the detection value and the second threshold value that changes over time, while executing the diagnosis control in which the connecting and disconnecting unit is controlled such that the power path is connected to the predetermined location via the resistor. When diagnosis control is executed, the power path and the predetermined location are connected via the resistor, and a current due to discharge of the floating capacitance of the power path flows between the power path and the predetermined location. When the detection unit is normal, the detection value changes with a time constant that is determined by the floating capacitance and the resistor. When an abnormality occurs in the detection unit, the time constant of the detection value becomes a time constant that is different from the detection value when the detection unit is normal. Accordingly, the detection unit can be diagnosed more appropriately by diagnosing the state of the detection unit based on the detection value and the second threshold value that changes over time. When a leakage current is occurring between the power path and the predetermined location during diagnosis control, a current due to discharge of the floating capacitance flows between the power path and the predetermined location without going through the resistor of the connecting and disconnecting unit, and the detection value changes over a smaller time constant than when the leakage current is not occurring, and exceeds the first threshold value. Accordingly, whether a leakage current is occurring is determined based on the detection value and the first threshold value, and also the state of the detection unit is diagnosed based on the detection value and the second threshold value that changes over time, while executing diagnosis control in which the connecting and disconnecting unit is controlled such that the power path is connected to the predetermined location via the resistor. Thus, whether a leakage current is occurring can be determined while diagnosing the detection unit. Now, examples of the “predetermined location” may include the ground, a housing of another device, or the like.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a configuration diagram illustrating an outline of a configuration of a charging station 20 on which a determining and diagnosing device according to the present embodiment is mounted;

FIG. 2 is an explanatory diagram for describing an exemplary temporal change in the detection voltage Vdet at the time of diagnosing the state of the detection unit 26 when the detection unit 26 is normal, the execution state of the upper limit determination that is the determination using the first threshold value Vth1 in the control device 30, the execution state of the lower limit determination that is the determination using the second threshold value Vth2 in the control device 30, the state of the negative relay Rln, and the state of the detection unit 26 in the control device 30;

FIG. 3 is an explanatory diagram for explaining an exemplary temporal change in the detection voltage Vdet in another embodiment, the execution state of the upper limit determination that is the determination using the first threshold value Vth1 in the control device 30, the execution state of the lower limit determination that is the determination using the second threshold value Vth2 in the control device 30, the state of the negative relay Rln, and whether the state can be diagnosed of the detection unit 26 in the control device 30;

FIG. 4 is an explanatory diagram for explaining an exemplary temporal change in the detection voltage Vdet in another embodiment, the execution state of the upper limit determination that is the determination using the first threshold value Vth1 in the control device 30, the execution state of the lower limit determination that is the determination using the second threshold value Vth2 in the control device 30, the state of the negative relay Rln, and whether the state can be diagnosed of the detection unit 26 in the control device 30;

FIG. 5 is an explanatory diagram for explaining a state of a temporal change in the ground fault current generated in the positive line-line 24a; and

FIG. 6 is a configuration diagram illustrating an outline of a configuration of a connecting and disconnecting unit 128 according to another embodiment.

### DETAILED DESCRIPTION OF EMBODIMENTS

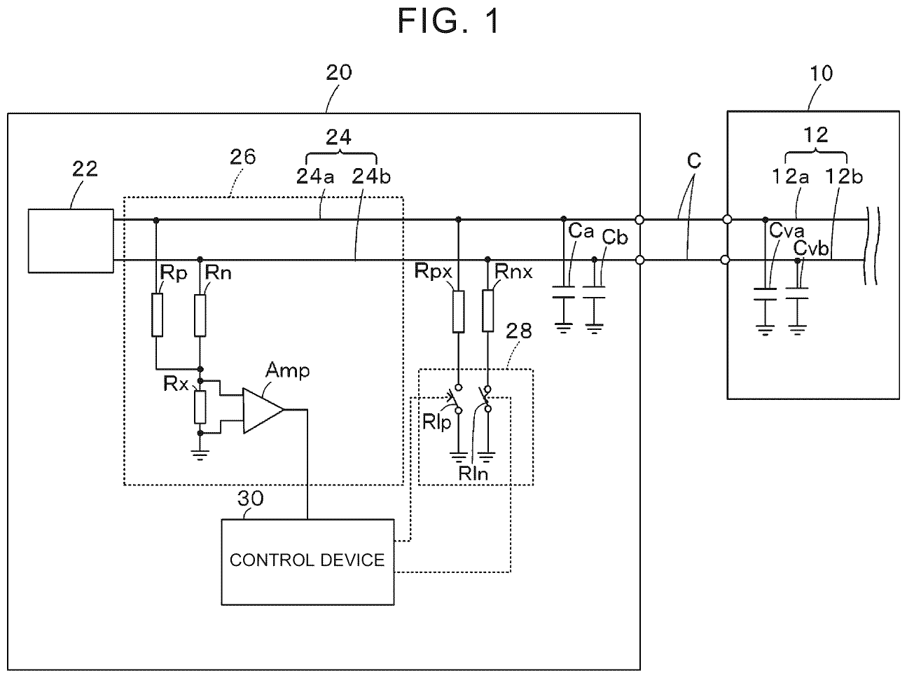

Embodiments of the present disclosure will be described with reference to the drawings. FIG. 1 is a configuration diagram illustrating an outline of a configuration of a charging station 20 on which a determining and diagnosing device according to the present embodiment is mounted. The charging station 20 is configured to supply electric power to a battery or the like mounted on the vehicle 10 by being connected to a power line 12 connected to a battery or the like (not shown) mounted on the vehicle 10 via a cable C. The charging station 20 includes a power outputting unit 22, a detection unit 26, a resistor Rpx, Rnx, a connecting and disconnecting unit 28, and a control device 30. The power line 12 is basically insulated from the ground (predetermined location). The power line 24 includes a floating capacitance Cva, Cvb between the power line and the ground.

The power outputting unit 22 supplies direct current power to the positive line 24a and the negative line 24b of the power line (power path) 24 connected to the cable C. The power line 24 is basically insulated from the ground (predetermined location). The power line 24 includes a floating capacitance Ca, Cb between the power line and the ground. The detection unit 26 includes a resistor Rp, Rn, Rx and an amplifier Amp.

One end of the resistor Rp is connected to the positive line 24a of the power line 24. One end of the resistor Rn is connected to the negative line 24b of the power line 24. The resistor Rx has one end connected to one end not connected to the positive line 24a of the resistor Rp and one end not connected to the negative line 24b of the resistor Rn, and the other end grounded. The amplifier Amp amplifies the voltage Vrx across the resistor Rx and outputs the amplified voltage as a detection voltage (detection value) Vdet to the control device 30. The voltage Vrx across the resistor Rx is a voltage obtained by dividing the voltage between the positive line 24a and the negative line 24b of the power line 24 by the resistor Rp, Rn. Here, the resistance value of the resistor Rx is sufficiently smaller than the resistance value of the resistor Rp, Rn. For example, when the resistance value of the resistor Rp, Rn is 500 kΩ, the resistance value of the resistor Rpx, Rnx may be 20 kΩ.

One end of the resistor Rpx is connected to the positive line 24a of the power line 24. One end of the resistor Rnx is connected to the negative line 24b of the power line 24.

The connecting and disconnecting unit 28 includes a positive-electrode relay Rlp and a negative-electrode relay Rln. The positive relay Rlp is grounded at one end which is not connected to the resistor Rpx and is connected to the positive line 24a via the resistor Rpx. The positive relay Rlp is connected to and disconnected from the positive line 24a via the resistor Rpx. The negative relay Rln is grounded at one end which is not connected to the resistor Rnx and is connected to the negative line 24b via the resistor Rnx. The negative relay Rln is connected to and disconnected from the negative line 24b via the resistor Rnx. The resistance value of the resistor Rpx, Rnx may be set to be substantially equal to the resistance value of the resistor Rp, Rn. For example, when the resistance value of the resistor Rp, Rn is 500 kΩ, the resistance value of the resistor Rpx, Rnx may be set to about 500 kΩ.

The control device 30 is configured as a microprocessor centered around a CPU, and in addition to the CPU, includes a RAM, a flash memory, an input/output port, a communication port, and the like that temporarily store ROM and data for storing a process program. The control device 30 receives the detected-voltage Vdet from the amplifier Amp. A control signal to the positive relay Rlp and the negative relay Rln is outputted from the control device 30.

In the charging station 20 equipped with the determining and diagnosing device of the present embodiment configured as described above, the control device 30 performs the upper limit determination for determining whether or not the detected-voltage Vdet from the amplifier Amp exceeds the first threshold value Vth1. Then, the control device 30 determines whether or not a ground fault current (leakage current) is generated in the power line 24, in particular, in the negative line 24b. The first threshold value Vth1 is a threshold value for determining whether or not a ground fault current is generated in the power line 24, and is set to an upper limit threshold value Vthmax that is larger than an upper limit of a range of voltages that the detected voltage Vdet can normally take when the ground fault current is not generated. When the detected voltage Vdet from the amplifier Amp is equal to or lower than the first threshold value Vth1, the control device 30 determines that a ground fault current is not generated in the power line 24. When the detected voltage Vdet exceeds the first threshold value Vth1 at a time rate of change equal to or higher than the predetermined rate, the control device 30 determines that a ground fault current is generated in the power line 24. As described above, it is possible to determine whether or not a ground fault current is generated in the power line 24 based on the detected voltage Vdet and the first threshold value Vth1.

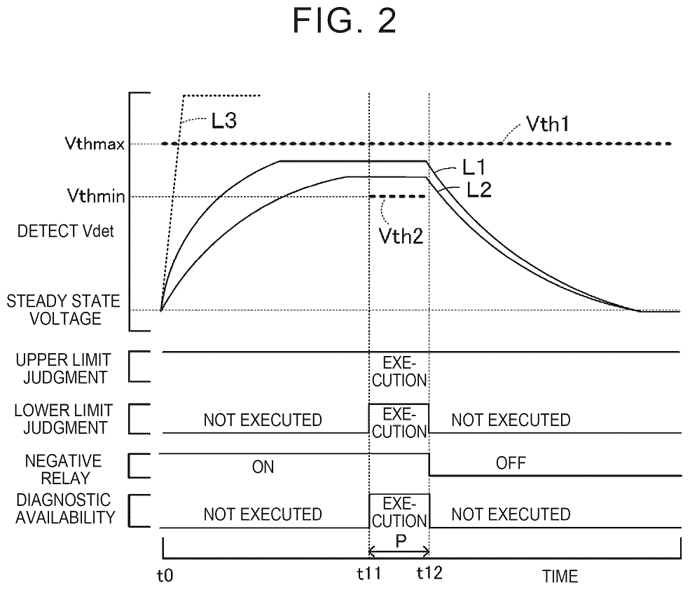

Next, the operation of the charging station 20 equipped with the determining and diagnosing device of the present embodiment configured in this way, in particular, the operation when diagnosing the state of the detection unit 26 (whether normal or not) will be described. FIG. 2 is an explanatory diagram for explaining an exemplary temporal change of a detection voltage Vdet at the time of diagnosing the state of the detection unit 26 when the detection unit 26 is normal, an execution state of the upper limit determination that is the determination using the first threshold value Vth1 in the control device 30, an execution state of the lower limit determination that is the determination using the second threshold value Vth2 in the control device 30, a state of the negative relay Rln, and a diagnosis possibility of the state of the detection unit 26 in the control device 30. Here, the first threshold value Vth1 and the second threshold value Vth2 are set to constant values regardless of the elapse of times.

In the charging station 20, when the detection unit 26 is diagnosed, the negative relay Rln is turned on, and the diagnosis control for connecting the negative line 24b to the ground via the resistor Rnx is started (temporal t0). By turning on the negative relay Rln, the floating capacitance Cvb of the negative line 12b of the power line 24 of the vehicle 10 and the charges of the floating capacitance Cb of the negative line 24b are discharged through the resistor Rnx. Then, a current simulating a ground fault is generated in the negative line 24b, and the voltage of the negative line 24b decreases. The voltage Vrx across the resistor Rx (corresponding to the detected voltage Vdet outputted from the amplifier Amp) is a voltage division between the positive line 24a and the negative line 24b. When the detection unit 26 is normal, the voltage Vrx, that is, the detection voltage Vdet, increases at a relatively large time constant until the discharging of the charges of the floating capacitance Cvb, Cb is completed, as indicated by the solid line L1 in the drawing. When discharging of the charges of the floating capacitance Cvb, Cb is completed, the detected voltage Vdet is saturated (between the time t11 and the time t12). Thereafter, when the negative relay Rln is turned off (time t12), the floating capacitance Cvb, Cb is charged and the voltage of the negative line 24b increases, and the detected voltage Vdet decreases. At this time, the time constant of detected voltage Vdet and the saturated voltage fluctuate due to variations in the circuitry connected to the power line 24, as shown by the solid line L1, L2. When an anomaly occurs in the detection unit 26, the detection voltage Vdet does not exhibit the above-described behavior of the solid line L1, L2, and the time constant of the detection voltage Vdet when the negative-electrode-relay Rln is turned on and the voltage in the saturated condition differ from those in the normal condition.

The control device 30 sets the second threshold value Vth2 to a lower limit threshold value Vthmin that is lower by a margin than a voltage estimated to be reached by the detection voltage Vdet in the saturation state, considering the variation of the detection voltage Vdet due to the circuit variation in the saturation state. Then, after turning on the negative relay Rln, the control device 30 considers the variation of the time constant of the detection voltage Vdet due to the circuit variation, the detection unit 26 diagnoses as normal when the detection voltage Vdet is equal to or greater than the second threshold value Vth2 and equal to or less than the first threshold value Vth1 in the period P (the period between the time t11 and the time t12 in the drawing) in which the detection voltage Vdet is estimated to be saturated. When the detected voltage Vdet is less than the second threshold value Vth2 or exceeds the first threshold value Vth1 in the period P, the control device 30 diagnoses that an anomaly has occurred in the detection unit 26. In this way, during the diagnosis control in which the negative relay Rln is turned on, the condition of the detection unit 26 is diagnosed based on whether the detection voltage Vdet is equal to or greater than the second threshold value Vth2 and equal to or less than the first threshold value Vth1 in the period P (by performing the upper limit determination and the lower limit determination). Thus, the detection unit 26 can be properly diagnosed. Even during such diagnosis control, the above-described ground fault determination can be executed by executing the upper limit determination. Thus, it is possible to determine whether or not a ground fault current indicated by a broken line L3 in the drawing is generated while diagnosing the detection unit 26.

According to the charging station 20 on which the determining and diagnosing device of the present embodiment described above is mounted, it is determined whether or not a ground fault current is generated based on the detection voltage Vdet and the first threshold value (first threshold value) Vth1, and the state of the detection unit 26 is diagnosed based on the detection voltage Vdet, the first threshold value Vth1, and a second threshold value (second threshold value) Vth2 that differs from the first threshold value Vth1 while executing the diagnosis control for controlling the connecting and disconnecting unit 28 so that the negative line 24b and the ground are connected. Thus, it is possible to determine whether or not a ground fault current is generated while diagnosing the detection unit 26.

When the detected voltage Vdet exceeds the first threshold value (first threshold value) Vth1 at a time rate of change equal to or higher than the predetermined rate, it is determined that a ground fault current is generated. When the detection voltage Vdet exceeds the first threshold value Vth1 during the execution of the diagnosis control and the detection voltage Vdet becomes less than the second threshold value Vth2 during the period P during the execution of the diagnosis control, it is diagnosed that an anomaly has occurred in the detection unit. Accordingly, it is possible to appropriately determine the occurrence of the leakage current and to diagnose the occurrence of the abnormality in the detection unit 26.

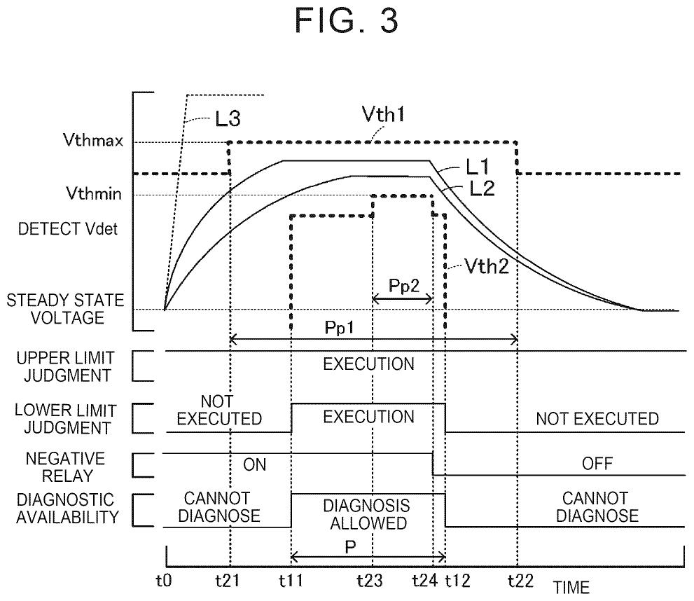

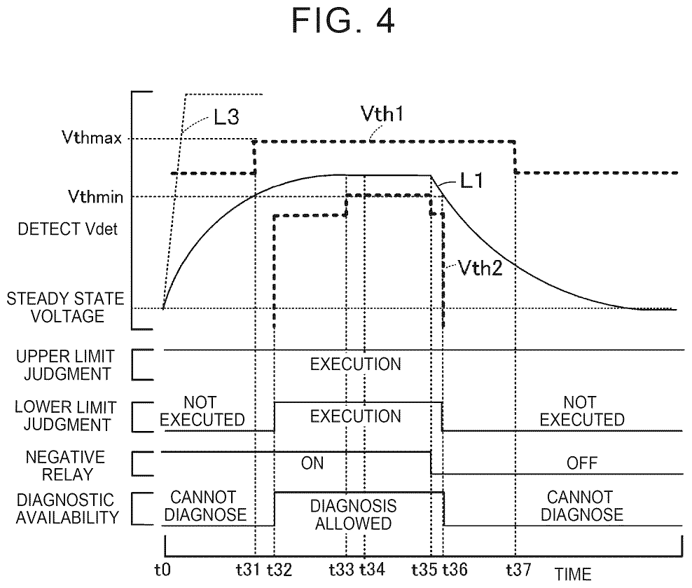

In the above-described embodiment, the first threshold value Vth1 and the second threshold value Vth2 are set to constant values (the upper limit threshold value Vthmax and the lower limit threshold value Vthmin) regardless of the elapse of time. However, as illustrated in another embodiment of FIG. 3, the first threshold value Vth1 and the second threshold value Vth2 may be changed according to the elapsed time since the diagnosis control is started to be executed. In this case, the waveform of the detection voltage Vdet when the detection unit 26 is normal may be obtained in advance by experimentation, analysis, or machine learning, and the first threshold value Vth1 and the second threshold value Vth2 may be set so as to avoid the waveform of the detection voltage Vdet. For example, as illustrated in FIG. 3, the first threshold value Vth1 may be set to be smaller than the upper limit threshold value Vthmax in a period before and after the period (first period) Pp1 between the time (first timing) t21 and the time (second timing) t22 after the diagnosis control is started. Further, the second threshold value Vth2 may be set to be smaller than the lower limit threshold value Vthmin in a period before and after the period (second period) Pp2 between the time (third timing) t23 and the time (fourth timing) t24 from the beginning of the period (predetermined period) P. In this way, it is possible to more appropriately determine the occurrence of the ground fault current and to diagnose the occurrence of the abnormality in the detection unit 26. Further, as illustrated in FIG. 4, when the detection voltage Vdet exceeds the lower threshold value Vthmin (time t31) the first threshold value Vth1 from a value lower than the upper limit threshold value Vthmax to the upper limit threshold value Vthmax, a predetermined time after the time t31 as a value lower than the lower limit threshold value Vthmin the second threshold value Vth2 at a time t32, and starts diagnosing the detection unit 26 using the first, second threshold value Vth1, Vth2. Then, the first threshold value Vth1 is set to the upper limit threshold value Vhmax and the second threshold value Vth2 is set to the lower limit threshold value Vthmin at a timing (time t33) at which the detected-voltage Vdet does not change. Then, the detection unit 26 continues diagnosing using the first and second threshold values Vth1, Vth2. Further, when the detection voltage Vdet does not change between the upper limit threshold value Vthmax and the lower limit threshold value Vthmin within a predetermined time tref1 from the time t33 (time t34), it is determined that the detection voltage Vdet is saturated. Then, the detection unit 26 continues diagnosing using the first and second threshold values Vth1, Vth2. When the predetermined time tref2 has elapsed from the time t34 (time t35), the second threshold value Vth2 is set to a value lower than the lower limit threshold value Vthmin and the negative relay Rln is turned off. Then, when the predetermined time tref3 has elapsed from the time t35 (time t36), the diagnosing of the detection unit 26 is ended. Further, when the predetermined time tref4 has elapsed from the time t35 (time t37), the first threshold value Vth1 is set to be smaller than the upper limit threshold value Vhmax. The voltage value and the time constant of the detected voltage Vdet vary depending on the floating capacitance Cva, Cvb of the power line 24 of the vehicle 10 connected to the charging station 20. Therefore, by temporally changing the first and second threshold value Vth1, Vth2 in accordance with the voltage of the detection voltage Vdet, it is possible to more appropriately determine the occurrence of a ground fault current and diagnose the occurrence of an anomaly in the detection unit 26.

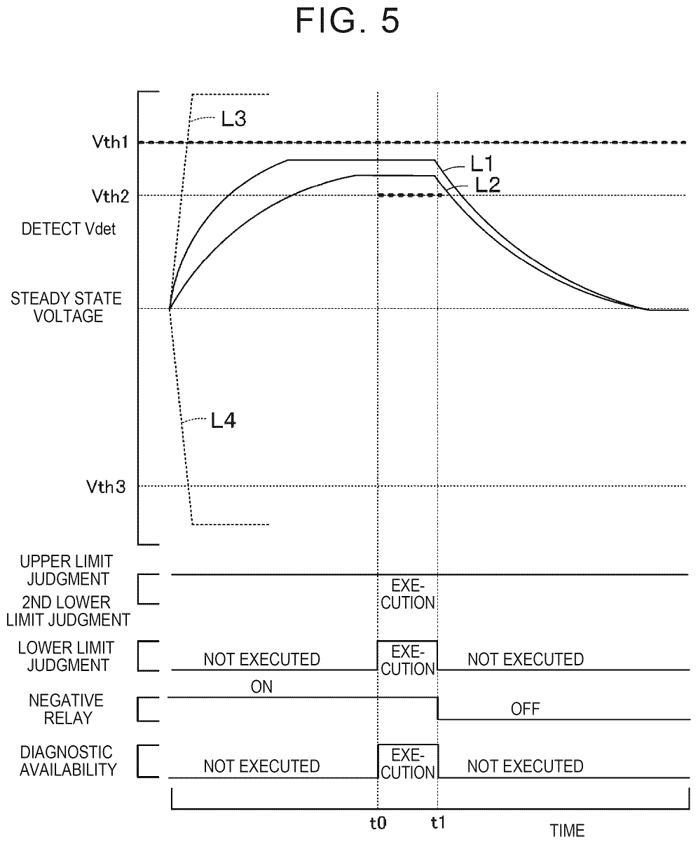

In the above-described embodiment, the control device 30 determines whether or not the detected voltage Vdet from the amplifier Amp exceeds the first threshold value Vth1, and determines whether or not a ground fault current is generated in the power line 24, in particular, the negative line 24b. However, it may be determined whether the detected voltage Vdet from the amplifier Amp is less than the third threshold value Vth3 to determine whether a ground fault current is generated in the power line 24, particularly in the positive line 24a. FIG. 5 is an explanatory diagram for explaining a state of temporal change of the ground fault current generated in the positive line-line 24a. The broken line L4 indicates a temporal change in the ground fault current generated in the positive line 24a. As shown in the drawing, when a ground fault current is generated in the positive line 24a, the detected voltage Vdet drops at a time rate of change equal to or higher than a predetermined rate. Therefore, the third threshold value Vth3 is set as a threshold value for determining whether or not a ground fault current has occurred. When the detected voltage Vdet from the amplifier Amp is equal to or higher than the third threshold value Vth3, it is determined that a ground fault current is not generated in the power line 24 (positive line 24a). When the detected voltage Vdet from the amplifier Amp becomes less than the third threshold value Vth3 at a time rate of change equal to or higher than the predetermined rate, it is determined that a ground fault current is generated in the power line 24 (positive line 24a). As described above, it is possible to determine whether or not a ground fault current is generated in the power line 24 based on the detected-voltage Vdet and the third-threshold value Vth3.

In the above-described embodiment, in the diagnosis control, the negative relay Rln is turned on, and the negative line 24b is connected to the ground via the resistor Rnx. However, in the diagnosis control, the positive relay Rlp may be turned on to connect the positive line 24a to the ground via the resistor Rpx. When the positive relay Rlp is turned on, charges of the floating capacitance Cva, Ca are discharged through the resistor Rpx, a ground fault occurs in the positive line 24a, and the positive line 24a is lowered. When the detection unit 26 is normal, the detection voltage Vdet outputted from the amplifier Amp drops at a relatively large time constant until the discharging of the charges of the floating capacitance Ca is completed. When discharging of the charges of the floating capacitance Ca is completed, the detected-voltage Vdet is saturated. After that, when the positive relay Rlp is turned off, the floating capacitance Ca is charged and the voltage of the positive line 24a rises, so that the detected voltage Vdet rises. The time constant of the detected voltage Vdet at this time and the voltage at the saturated condition fluctuate due to variations in the circuitry connected to the power line 24. The control device 30 sets the fourth threshold value Vth4 to be larger than the voltage estimated to be reached by the detection voltage Vdet in the saturation state by a margin and larger than the third threshold value Vth3 illustrated in FIG. 5 in view of the variation of the detection voltage Vdet in the saturation state. Then, the control device 30 diagnoses that the detection unit 26 is normal when the detection voltage Vdet is equal to or lower than the fourth threshold value Vth4 and equal to or higher than the third threshold value Vth3 during the period P2 in which the detection voltage Vdet is estimated to be saturated while the diagnosis control is being executed in view of the variation in the time constant of the detection voltage Vdet. When the detected voltage Vdet exceeds the fourth threshold value Vth4 or is less than the third threshold value Vth3 in the period P2, the control device 30 diagnoses that an anomaly has occurred in the detection unit 26. As described above, the detection unit 26 can be properly diagnosed by diagnosing the status of the detection unit 26 on the basis of the detection voltage Vdet and the third and fourth threshold value Vth3, Vth4 in the period P2 while the diagnosis control is being executed. During such diagnosis control, it is also possible to determine whether or not a ground fault current (leakage current) has occurred in the power line 24 based on the detected-voltage Vdet and the third-threshold value Vth3.

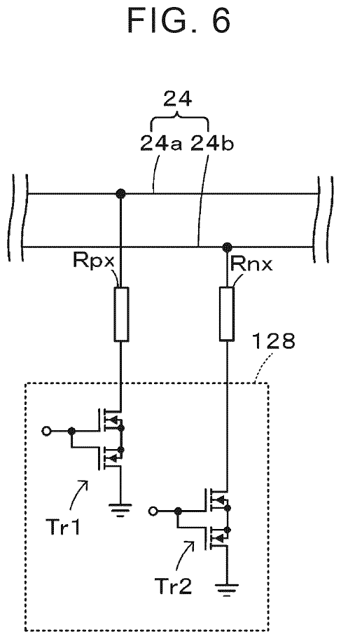

In the above-described embodiment, the connecting and disconnecting unit 28 includes a positive relay Rlp and a negative relay Rln. However, the connecting and disconnecting unit 28 may be configured to connect and disconnect the power line 24 and the ground. Accordingly, as illustrated in the connecting and disconnecting unit 128 of the other embodiment of FIG. 6, a transistor Tr1, Tr2 such as a MOSFET may be attached instead of the positive-electrode relay Rlp and the negative-electrode relay Rln to turn on and off the transistor Tr1, Tr2 to thereby connect and disconnect the resistor connected to the power line 24 and the ground. Further, in the connecting and disconnecting unit 28, a constant current circuit may be attached in place of the positive relay Rlp and the negative relay Rln, and the current value of the constant current circuit may be switched between a relatively large current I1 and a current value I2 that can be regarded as being substantially zero, so that the power line 24 may be connected to the ground and disconnected from the ground.

In the above-described embodiment, the detection unit 26 determines whether or not a ground fault current (leakage current) is generated in the negative line 24b based on the detection voltage Vdet from the amplifier Amp based on the voltage Vrs of the resistor Rx and the first threshold value Vth1. However, the detection unit 26 only needs to be able to detect the current flowing between the power line 24 and the ground via the resistor Rn, Rp. For example, instead of the resistor Rx and the amplifier Amp, a current flowing between the power line 24 and the ground via a resistor Rn, Rp, such as a current transformer, may be detected.

In the above-described embodiment, the second threshold values Vth2 and P are adjusted in accordance with variations in the detected voltage Vdet and time constants due to variations in the circuitry connected to the power lines 24. However, the voltage and the time constant of the detected voltage Vdet vary depending on the floating capacitance Cva, Cvb of the power line 24 of the vehicle 10 connected to the charging station 20. Therefore, the individual information of the vehicle 10 (manufacturer or vehicle type, car name, vehicle type, vehicle identification number, etc.) is received from the vehicle 10 such as a communication, it may be adjusted period P and the second threshold value Vth2 in accordance with the individual information of the vehicle 10.

In the above-described embodiment, the detection unit 26 detects a ground fault in the power line 24 of the charging station 20. However, the detection unit 26 is not limited to detecting a ground fault of the power line 24 of the charging station 20, and may detect a leakage current to a nearby metal casing.

The correspondence between the main elements of the embodiments and the main elements of the disclosure described in the column of the means for solving the problem will be described. In the embodiment, the connecting and disconnecting unit 28 corresponds to the “connection release unit”, and the control device 30 corresponds to the “determining and diagnosing unit”.

The correspondence between the main elements of the embodiment and the main elements of the disclosure described in the section of the means for solving the problem is an example for specifically explaining the embodiment of the disclosure described in the section of the means for solving the problem. Therefore, the elements of the disclosure described in the section of the means for solving the problem are not limited. That is, the interpretation of the disclosure described in the section of the means for solving the problem should be performed based on the description in the section, and the embodiments are only specific examples of the disclosure described in the section of the means for solving the problem.

While embodiments for carrying out the present disclosure have been described above, it is needless to say that the present disclosure is not limited to such embodiments, and various embodiments can be implemented without departing from the gist of the present disclosure

The present disclosure is applicable to a manufacturing industry of a determining and diagnosing device and the like.

What is claimed is:

1. A determining and diagnosing device that determines whether a leakage current is occurring based on a detection value from a detection unit that detects a current flowing between a power path and a predetermined location, and also that diagnoses a state of the detection unit, the determining and diagnosing device comprising:
a connecting and disconnecting unit for connecting and disconnecting a resistor that is connected to the power path and the predetermined location; and
a determining and diagnosing unit that determines whether the leakage current is occurring based on the detection value and a first threshold value, and also diagnoses the state of the detection unit based on the detection value, the first threshold value, and a second threshold value that is different from the first threshold value, while executing diagnosis control in which the connecting and disconnecting unit is controlled such that the power path and the predetermined location are connected.

2. The determining and diagnosing device according to claim 1, wherein
the detection unit detects a current flowing between the power path and the predetermined location as a voltage, and
the determining and diagnosing unit
sets the second threshold value to be lower than the first threshold value,
determines that the leakage current is occurring when the detection value exceeds the first threshold value at a time rate of change that is no smaller than a predetermined rate, and
diagnoses that an abnormality is occurring in the detection unit when the detection value is no smaller than the first threshold value during execution of the diagnosis control, and when the detection value is smaller than the second threshold value within a predetermined period during execution of the diagnosis control.

3. The determining and diagnosing device according to claim 1, wherein at least one of the first threshold value and the second threshold value changes over time in accordance with an amount of elapsed time since starting of the diagnosis control.

4. The determining and diagnosing device according to claim 2, wherein
the determining and diagnosing unit
reduces the first threshold value before and after a first period that is between a first timing and a second timing after starting the diagnosis control, in comparison with during the first period, and
reduces the second threshold value before and after a second period that is between a third timing and a fourth timing after starting the predetermined period, in comparison with during the second period.

5. A determining and diagnosing device that determines whether a leakage current is occurring based on a detection value from a detection unit that detects a current flowing between a power path and a predetermined location, and also that diagnoses a state of the detection unit, the determining and diagnosing device comprising:
a connecting and disconnecting unit for connecting and disconnecting a resistor that is connected to the power path and the predetermined location; and
a determining and diagnosing unit that determines whether the leakage current is occurring based on the detection value and a first threshold value, and also diagnoses the state of the detection unit based on the detection value, and a second threshold value that changes over time, while executing diagnosis control in which the connecting and disconnecting unit is controlled such that the power path and the predetermined location are connected.
